(19) United States
(12) Patent Application Publication
(10) Pub. No.: US 2021/0034957 A1
(43) Pub. Date: Feb. 4, 2021

(54) NEURAL NETWORK ACCELERATION SYSTEM AND OPERATING METHOD THEREOF

(71) Applicant: KOREA ADVANCED INSTITUTE OF SCIENCE AND TECHNOLOGY, Daejeon (KR)

(72) Inventors: Minsoo RHU, Daejeon (KR); Youngeun KWON, Daejeon (KR); YunJae LEE, Daejeon (KR)

(73) Assignee: KOREA ADVANCED INSTITUTE OF SCIENCE AND TECHNOLOGY, Daejeon (KR)

(21) Appl. No.: 16/922,333

(22) Filed: Jul. 7, 2020

(30) Foreign Application Priority Data
Jul. 30, 2019 (KR) 10-2019-0092337

(51) Int. Cl. G06N 3/063; G06F 9/50; G06K 9/62; G06F 17/16

(52) U.S. Cl. CPC G06N 3/063; G06F 9/5027; G06N 3/08; G06F 17/16; G06K 9/6261

(57) ABSTRACT

Disclosed are a neural network acceleration system and an operating method of the same. The neural network acceleration system includes a first memory module that generates a first reduced embedding segment through a tensor operation, based on a first segment of a first embedding and a second segment of a second embedding, a second memory module that generates a second reduced embedding segment through the tensor operation, based on a third segment of the first embedding and a fourth segment of the second embedding, and a processor that processes a reduced embedding including the first reduced embedding segment and the second reduced embedding segment, based on a neural network algorithm.

### CROSS-REFERENCE TO RELATED APPLICATIONS

This application claims priority under 35 U.S.C. § 119 to Korean Patent Application No. 10-2019-0092337 filed on Jul. 30, 2019, in the Korean Intellectual Property Office, the disclosures of which are incorporated by reference herein in their entireties.

### BACKGROUND

Embodiments of the inventive concept described herein relate to an acceleration system, and more particularly, relate to a neural network acceleration system and an operating method thereof.

A neural network acceleration system is a computing system that processes data, based on artificial intelligence/machine learning/deep-learning algorithms. The neural network acceleration system may learn input data to generate embedding, and may perform an inference and a training operation through the embedding. The neural network acceleration system using the embedding may be used for natural language processing, advertisements, recommendation systems, speech recognitions, etc.

The neural network acceleration system may include a processor for performing the inference and training operation using the embedding. Since a data size of the embedding is very large, the embedding may be stored in a high capacity memory external to the processor. The processor may receive the embedding from the memory external to the processor to perform the inference and training operation. To perform the inference and training operation quickly, the embedding stored in the memory needs to be quickly transferred to the processor. That is, the embedding-based neural network acceleration system requires a high capacity memory and a high memory bandwidth.

### SUMMARY

Embodiments of the inventive concept provide a neural network acceleration system capable of providing a high capacity memory and a high memory bandwidth, and a method of operating the same.

According to an embodiment of the inventive concept, a neural network acceleration system comprising: a first memory module that generates a first reduced embedding segment through a tensor operation, based on a first segment of a first embedding and a second segment of a second embedding, a second memory module that generates a second reduced embedding segment through the tensor operation, based on a third segment of the first embedding and a fourth segment of the second embedding, and a processor that processes a reduced embedding including the first reduced embedding segment and the second reduced embedding segment, based on a neural network algorithm.

According to an embodiment, the first embedding may correspond to a first object of a specific category, and the second embedding may correspond to a second object of the specific category.

According to an embodiment, the first memory module may include at least one memory device that stores the first segment and the second segment, and a tensor operator that performs the tensor operation, based on the first segment and the second segment.

According to an embodiment, the at least one memory device may be implemented as a dynamic random access memory.

According to an embodiment, a size of the first segment may be the same as a size of the third segment.

According to an embodiment, the a data size of the reduced embedding may be less than a total data size of the first embedding and the second embedding.

According to an embodiment, the tensor operation may include at least one of an addition operation, a subtraction operation, a multiplication operation, a concatenation operation, and an average operation.

According to an embodiment, the system may further include a bus that transfers the first reduced embedding segment from the first memory module and the second reduced embedding segment from the second memory module to the processor, based on a preset bandwidth.

According to an embodiment, the first memory module may further configured to gather the first segment and the second segment in a memory space corresponding to consecutive addresses, and the first reduced embedding segment may be generated based on the gathered first and second segments.

According to an embodiment of the inventive concept, a neural network acceleration system includes a first memory module that generates a first reduced embedding segment through a tensor operation, based on a first segment of a first embedding and a second segment of a second embedding, a second memory module that generates a second reduced embedding segment through the tensor operation, based on a third segment of the first embedding and a fourth segment of the second embedding, a main processor that receives the first reduced embedding segment and the second reduced embedding segment through a first bus, and a dedicated processor that processes a reduced embedding including the first reduced embedding segment and the second reduced embedding segment, which are transferred through a second bus, based on a neural network algorithm.

According to an embodiment, the first embedding may correspond to a first object of a specific category, and the second embedding may correspond to a second object of the specific category.

According to an embodiment, the first memory module may include at least one memory device that stores the first segment and the second segment, and a tensor operator that performs the tensor operation, based on the first segment and the second segment.

According to an embodiment, the first bus may be configured to transfer the first reduced embedding segment and the second reduced embedding segment from the first memory module and the second memory module, respectively, to the main processor, based on a first bandwidth, and the second bus may be configured to transfer the first reduced embedding segment and the second reduced embedding segment from the main processor to the dedicated processor, based on a second bandwidth.

According to an embodiment, the main processor may be further configured to store the first segment generated by splitting the first embedding and the second segment generated by splitting the second embedding in the first memory module, and may be further configured to store the third segment generated by splitting the first embedding and the fourth segment generated by splitting the second embedding in the second memory module.

According to an embodiment, the main processor may be further configured to split the first embedding such that a data size of the first segment is the same as a data size of the third segment, and may be further configured to split the second embedding such that a data size of the second segment is the same as a data size of the fourth segment.

According to an embodiment, the dedicated processor may include at least one of a graphic processing device and a neural network processing device.

According to an embodiment, the first memory module may be further configured to gather the first segment and the second segment in a memory space corresponding to consecutive addresses, and the first reduced embedding segment may be generated based on the gathered first and second segments.

According to an embodiment of the inventive concept, a method of operating a neural network acceleration system including a first memory module, a second memory module, and a processor, includes storing, by the processor, a first segment generated by splitting a first embedding and a second segment generated by splitting a second embedding in the first memory module, and storing, by the processor, a third segment generated by splitting the first embedding and a fourth segment generated by splitting the second embedding in the second memory module, generating, by the first memory module, a first reduced embedding segment through a tensor operation, based on the first segment and the second segment, and generating, by the second memory module, a second reduced embedding segment through the tensor operation, based on the third segment and the fourth segment, and processing, by the processor, a reduced embedding including the first reduced embedding segment and the second reduced embedding segment, based on a neural network algorithm.

According to an embodiment, the first embedding may correspond to a first object of a specific category, and the second embedding may correspond to a second object of the specific category.

According to an embodiment, the generating, by the first memory module, of the first reduced embedding segment may include gathering, by the first memory module, the first segment and the second segment in a memory space corresponding to consecutive addresses, and generating the first reduced embedding segment, based on the gathered first and second segments.

### BRIEF DESCRIPTION OF THE FIGURES

The above and other objects and features of the inventive concept will become apparent by describing in detail exemplary embodiments thereof with reference to the accompanying drawings.

FIG. 1 is a block diagram illustrating a neural network acceleration system according to an embodiment of the inventive concept.

FIG. 2 is a block diagram illustrating a neural network acceleration system according to another embodiment of the inventive concept.

FIG. 3 is a flowchart describing an operation of a neural network acceleration system according to an embodiment of the inventive concept.

FIG. 4 is a diagram illustrating embedding segments according to an embodiment of the inventive concept.

FIG. 5 is a diagram illustrating a reduced embedding according to an embodiment of the inventive concept.

FIGS. 6A to 6D are block diagrams illustrating a memory module according to an embodiment of the inventive concept.

FIG. 7 is a block diagram illustrating an example of a buffer device of FIGS. 6A to 6D.

FIG. 8 is a block diagram illustrating an expanded example of a neural network acceleration system according to embodiments of the inventive concept.

### DETAILED DESCRIPTION

Hereinafter, embodiments of the inventive concept will be described clearly and in detail such that those skilled in the art may easily carry out the inventive concept.

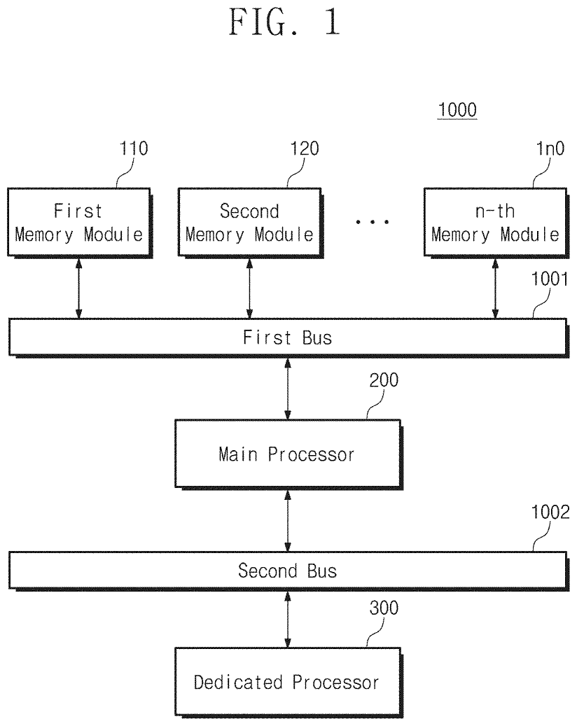

FIG. 1 is a block diagram illustrating a neural network acceleration system according to an embodiment of the inventive concept. Referring to FIG. 1, a neural network acceleration system 1000 may include first to nth memory modules 110 to 1n0, a main processor 200, a dedicated processor 300, a first bus 1001, and a second bus 1002. For example, the neural network acceleration system 1000 may be implemented as one of a desktop, a laptop, an embedded system, a server, an automobile, a mobile device, and an artificial intelligence system.

Each of the memory modules 110 to 1n0 may operate under a control of the main processor 200. In an exemplary embodiment, each of the memory modules 110 to 1n0 may write data provided from the main processor 200 in the internal memory, or may output data stored in the internal memory and may transmit the data to the main processor 200. In this case, each of the memory modules 110 to 1n0 may communicate the data with the main processor 200 through the first bus 1001.

Each of the memory modules 110 to 1n0 may include a volatile memory such as a dynamic random access memory (DRAM), and a nonvolatile memory such as a flash memory, a phase change memory (PRAM), etc. For example, each of the memory modules 110 to 1n0 may be implemented with an RDIMM (Registered DIMM), an LRDIMM (Load Reduction DIMM), a NVDIMM (Non Volatile DIMM) type, etc., which are based on a dual in-line memory module (DIMM) standard. However, the inventive concept is not limited thereto, and each of the memory modules 110 to 1n0 may be implemented as semiconductor packages having various form factors.

The memory modules 110 to 1n0 in FIG. 1 are illustrated as being “n” modules, but the neural network acceleration system 1000 may include one or more memory modules.

The main processor 200 may include a central processing unit (CPU) or an application processor that controls the neural network acceleration system 1000 and performs various operations. For example, the main processor 200 may control the memory modules 110 to 1n0 and the dedicated processor 300.

The main processor 200 may store codes required for performing neural network-based operations and data accompanying operations in the memory modules 110 to 1n0. For example, the main processor 200 may store input data including parameters, data sets, etc., associated with a neural network in the memory modules 110 to 1n0.

The dedicated processor 300 may perform the inference and training operation, based on various neural network algorithms under the control of the main processor 200. Accordingly, the dedicated processor 300 may include an operator or an accelerator that performs various operations. For example, the dedicated processor 300 may be implemented as one of operation devices that perform neural network-based operations, such as a graphics processing unit (GPU) or a neural processing unit (NPU).

The dedicated processor 300 may communicate data with the main processor 200 through the second bus 1002. For example, the dedicated processor 300 may receive data stored in the memory modules 110 to 1n0 through the main processor 200. The dedicated processor 300 may perform the inference and training operation, based on the received data. The dedicated processor 300 may transmit data generated based on the inference and training operation to the main processor 200.

The first bus 1001 may provide channels between the memory modules 110 to 1n0 and the main processor 200. A bandwidth of the first bus 1001 may be determined by the number of channels. For example, the first bus 1001 may be based on one of various standards such as a Peripheral Component Interconnect express (PCIe), a Nonvolatile Memory Express (NVMe), an Advanced eXtensible Interface (AXI), an ARM Microcontroller Bus Architecture (AMBA), NVLink, etc.

The second bus 1002 may transfer data between the main processor 200 and the dedicated processor 300. For example, the second bus 1002 may be based on one of various standards such as the PCIe, the AXI, the AMBA, the NVLink, etc.

In an exemplary embodiment, the main processor 200 may store embeddings in the memory modules 110 to 1n0. In this case, the embedding is a value in which the input data is converted into a vector or a multidimensional tensor form through learning, and may indicate information of a specific object in a specific category. For example, the embedding may correspond to each user information in a user category, or may correspond to each item in an item category. The embedding may be used for natural language processing, recommendation systems, advertisements, speech recognitions, etc., but the inventive concept is not limited thereto.

In an exemplary embodiment, the memory modules 110 to 1n0 may perform a tensor operation (or tensor manipulation), based on stored embeddings. The memory modules 110 to 1n0 may generate new embedding (hereinafter referred to as “reduced embedding”) through the tensor operation. In this case, the tensor operation may be a reduction operation including an addition operation, a subtraction operation, a multiplication operation, a concatenation operation, and an average operation. For example, the memory modules 110 to 1n0 may generate the reduced embedding by performing the tensor operation, based on a first embedding and a second embedding. In this case, a data size of the reduced embedding may be the same as a data size of each of the first embedding and the second embedding, but may be less than a total data size of the first embedding and the second embedding. That is, the memory modules 110 to 1n0 may generate the reduced embedding by preprocessing the stored embeddings.

In an exemplary embodiment, the main processor 200 may receive the reduced embedding from the memory modules 110 to 1n0 through the first bus 1001 and may process the reduced embedding, based on the neural network. That is, the main processor 200 may directly perform the inference and training operation, based on the reduced embedding without using the dedicated processor 300.

In another embodiment, the main processor 200 may receive the reduced embedding from the memory modules 110 to 1n0 and may transfer the reduced embedding to the dedicated processor 300 through the second bus 1002. In this case, the dedicated processor 300 may process the reduced embedding, based on the neural network. That is, the dedicated processor 300 may perform the inference and training operation, by using the reduced embedding. However, the inventive concept is not limited thereto, and the inference and training operation may be performed by both the main processor 200 and the dedicated processor 300.

As described above, the neural network acceleration system 1000 may perform the inference and training operation, based on the embedding. In this case, the memory modules 110 to 1n0 may preprocess the stored embeddings without using the main processor 200 and the dedicated processor 300, and may generate the reduced embeddings through the preprocessing. Accordingly, at least one of the main processor 200 and the dedicated processor 300 may receive the reduced embedding from the memory modules 110 to 1n0 and may perform the inference and training operation, based on the received reduced embedding. The reduced embedding may be transferred to the main processor 200 and the dedicated processor 300 through the first bus 1001 and the second bus 1002.

When the embeddings stored by the memory modules 110 to 1n0 are not preprocessed, the unpreprocessed embeddings may be transferred to the main processor 200 and the dedicated processor 300 through the first bus 1001 and the second bus 1002. Since each of the first bus 1001 and the second bus 1002 has a limited bandwidth and the data sizes of the embeddings are very large, a latency that transfers the embeddings to the main processor 200 and the dedicated processor 300 may be large. Accordingly, a time required for the inference and training operation may be increased.

When the reduced embedding generated through the preprocessing is transferred to the main processor 200 and the dedicated processor 300 through the first bus 1001 and the second bus 1002, since the data size of the reduced embedding is relatively small compared to the unpreprocessed embeddings, the reduced embedding may be transferred faster than the embeddings (i.e., latency is reduced). Accordingly, the time required for the inference and training operation may be reduced. That is, the neural network acceleration system 1000 may quickly perform the inference training operation by reducing the data size of embedding transferred under the limited bandwidth.

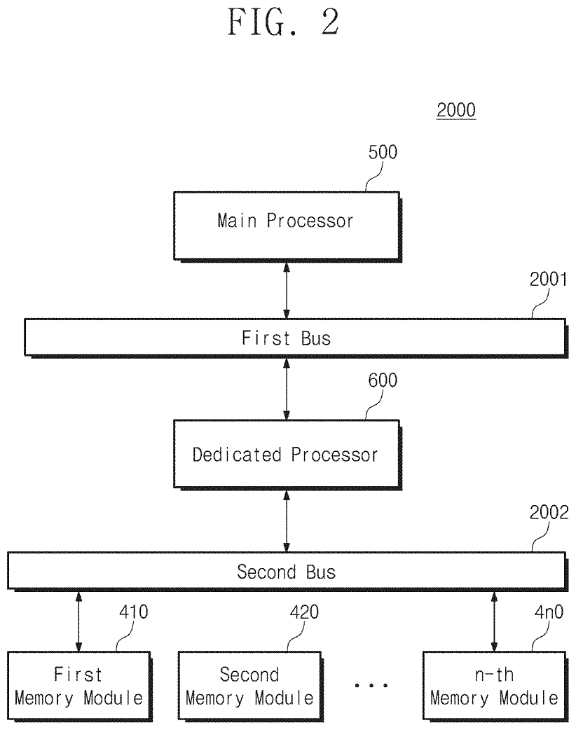

FIG. 2 is a block diagram illustrating a neural network acceleration system according to another embodiment of the inventive concept. Referring to FIG. 2, a neural network acceleration system 2000 includes first to nth memory modules 410 to 4n0, a main processor 500, a dedicated processor 600, a first bus 2001, and a second bus 2002. Since the components of the neural network acceleration system 2000 operate similarly to the components of the neural network acceleration system 1000 of FIG. 1, additional description may be omitted to avoid redundancy.

The main processor 500 may perform the inference and training operation by controlling the dedicated processor 600. The dedicated processor 600 may perform the inference and training operation, based on various neural network algorithms under the control of the main processor 500. The dedicated processor 600 may perform the inference and training operation, based on data provided from the memory modules 410 to 4n0. The memory modules 410 to 4n0 may store data in an internal memory or output data stored in the internal memory under the control of the main processor 500 or the dedicated processor 600.

The main processor 500 may communicate with the dedicated processor 600 through the first bus 2001, and the dedicated processor 600 may communicate with the memory modules 410 to 4n0 through the second bus 2002. For example, the first bus 2001 may be based on one of various standards such as the PCIe, the AXI, the AMBA, the NVLink, etc. The second bus 2002 may be based on an interface protocol having a bandwidth equal to or greater than that of the first bus 2001. For example, the second bus 2002 may be based on one of a Common Application Programming Interface (CAPI), a Gen-Z, a Cache Coherent Interconnect for Accelerators (CCIX), a Compute Express Link (CXL), the NVLink, and a BlueLINK. However, the inventive concept is not limited thereto, and the second bus 2002 may be based on one of various standards such as the PCIe, the NVMe, the AXI, the AMBA, etc.

In an exemplary embodiment, the memory modules 410 to 4n0 may store the embeddings. The memory modules 410 to 4n0 may perform the tensor operation, based on the stored embeddings. The memory modules 410 to 4n0 may generate the reduced embedding through tensor operation. That is, the memory modules 410 to 4n0 may generate the reduced embedding by preprocessing the embedding.

In an exemplary embodiment, the dedicated processor 600 may receive the reduced embedding from the memory modules 410 to 4n0 through the second bus 2002, and may process the reduced embedding, based on the neural network. That is, the dedicated processor 600 may perform the inference and training operation by using the reduced embedding.

As described above, the neural network acceleration system 2000 may perform the inference and training operation, based on the embedding. In this case, the dedicated processor 600 may receive the reduced embedding directly from the memory modules 410 to 4n0 through the second bus 2002. That is, the dedicated processor 600 may receive the reduced embedding without passing through the first bus 2001 and may perform the inference and training operation using the reduced embedding. Accordingly, the neural network acceleration system 2000 may perform the inference and training operation faster than the neural network acceleration system 1000 of FIG. 1.

In the following, for convenience of explanation, an operation of the neural network acceleration system according to embodiments of the inventive concept will be described in detail, based on the neural network acceleration system 1000 of FIG. 1.

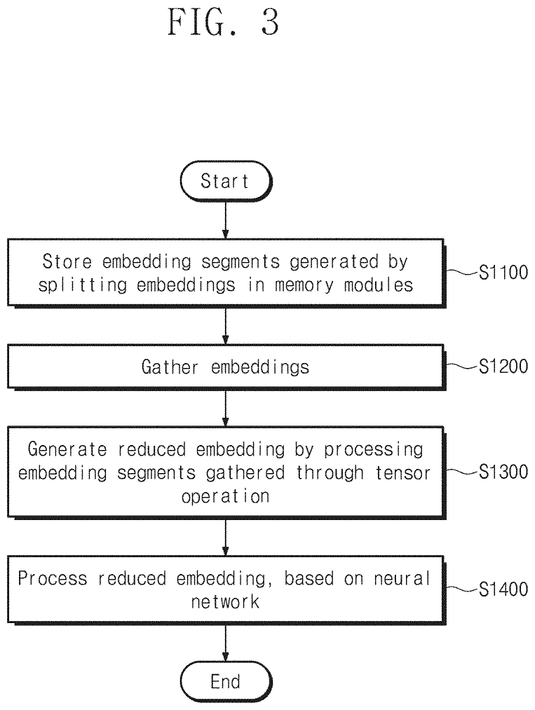

FIG. 3 is a flowchart describing an operation of a neural network acceleration system according to an embodiment of the inventive concept. Referring to FIGS. 1 and 3, in operation S1100, the neural network acceleration system 1000 may store embedding segments generated by splitting the embeddings in the memory modules 110 to 1n0. For example, the main processor 200 may generate the embedding segments by splitting embeddings, based on a preset criterion. The main processor 200 may assign the embedding segments to the memory modules 110 to 1n0 such that the generated embedding segments are distributed and stored in the memory modules 110 to 1n0.

In operation S1200, the neural network acceleration system 1000 may gather embeddings (i.e., embedding lookup). For example, in the inference and training operation, each of the memory modules 110 to 1n0 may gather at least one of the stored embedding segments without using the main processor 200. In this case, the gathered embedding segments may be stored in a memory space (hereinafter, referred to as a consecutive address space) corresponding to consecutive addresses among the memory spaces of each of the memory modules 110 to 1n0. That is, in the embedding lookup operation, the embedding segments may not be transferred to the main processor 200.

In operation S1300, the neural network acceleration system 1000 may generate the reduced embedding by processing the embedding segments gathered through the tensor operation. For example, in the inference and training operation, each of the memory modules 110 to 1n0 may perform the tensor operation with respect to the gathered embedding segments. Accordingly, the memory modules 110 to 1n0 may generate the reduced embedding. The memory modules 110 to 1n0 may transmit the reduced embedding to the main processor 200 through the first bus 1001.

In operation S1400, the neural network acceleration system 1000 may process the reduced embedding, based on the neural network. As one example, the main processor 200 may process the reduced embedding transmitted from the memory modules 110 to 1n0, based on the neural network. As another example, the main processor 200 may transfer the reduced embedding to the dedicated processor 300 through the second bus 1002. The dedicated processor 300 may process the reduced embedding transmitted from the main processor 200, based on the neural network.

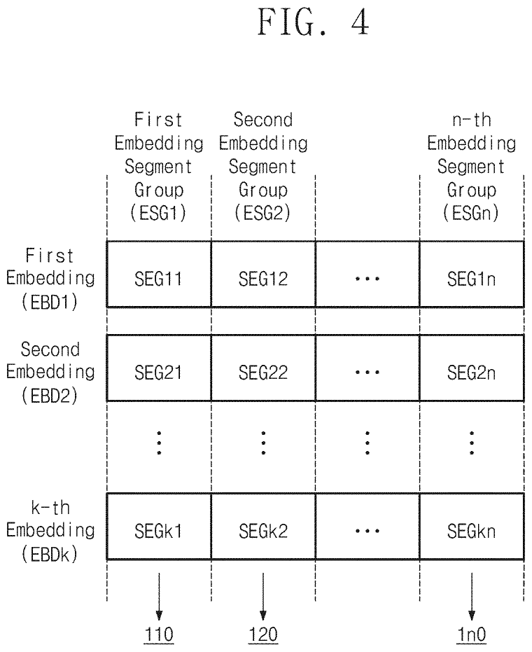

FIG. 4 is a diagram illustrating embedding segments according to an embodiment of the inventive concept. An operation of operation S1100 of FIG. 3 will be described in detail with reference to FIG. 4.

Referring to FIGS. 1 and 4, the main processor 200 may split each of first to k-th embeddings EBD1 to EBDk. The first to k-th embeddings EBD1 to EBDk may respectively correspond to objects of the same category. For example, the first embedding EBD1 may correspond to a first user in the user category, and the second embedding EBD2 may correspond to a second user in the user category.

The main processor 200 may generate the embedding segments by splitting each of the embeddings EBD1 to EBDk. For example, the main processor 200 may split the first embedding EBD1 to generate embedding segments SEG11 to SEG1n. Specifically, the main processor 200 may split the first embedding EBD1 into “n” numbers depending on the number of the memory modules 110 to 1n0. The main processor 200 may split the first embedding EBD1 such that each of the embedding segments SEG11 to SEG1n has the same size. However, the inventive concept is not limited thereto, and the main processor 200 may split the embedding according to various criteria.

The main processor 200 may store the embedding segments in the memory modules 110 to 1n0. The main processor 200 may assign the embedding segments in the memory modules 110 to 1n0 such that the embedding segments are distributed and stored in the memory modules 110 to 1n0. For example, the main processor 200 may store embedding segment groups ESG1 to ESGn in the memory modules 110 to 1n0, respectively. In this case, the first memory module 110 may store the first embedding segment group ESG1. The first embedding segment group ESG1 may include the embedding segments SEG11 and SEG21 to SEGk1. The embedding segments SEG11 and SEG21 to SEGk1 may correspond to the first to k-th embeddings EBD1 to EBDk, respectively. The second memory module 120 may store a second embedding segment group ESG2. The second embedding segment group ESG2 may include embedding segments SEG12 and SEG22 to SEGk2. The embedding segments SEG12 and SEG22 to SEGk2 may correspond to the first to k-th embeddings EBD1 to EBDk, respectively. That is, each of the memory modules 110 to 1n0 may store the embedding segment group constituting the embeddings EBD1 to EBDk.

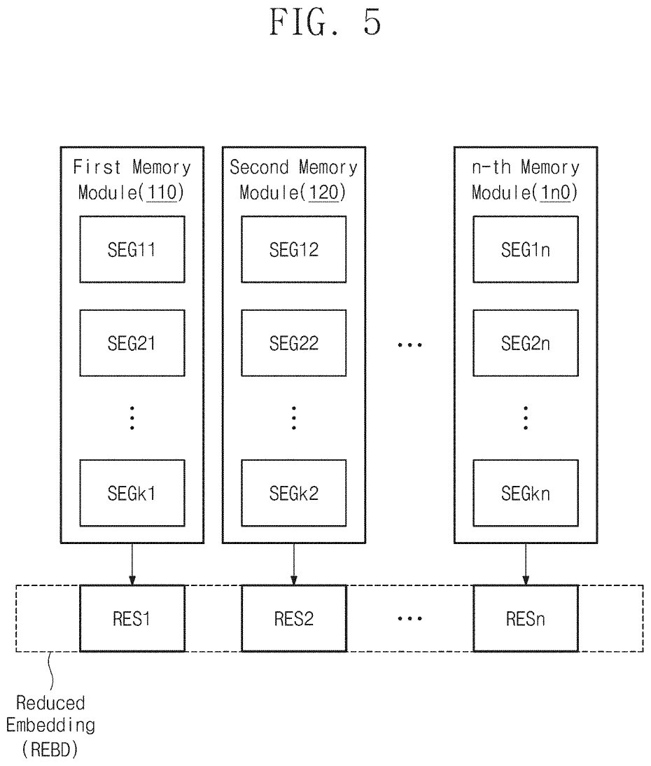

FIG. 5 is a diagram illustrating a reduced embedding according to an embodiment of the inventive concept. Operation of operations S1200 and S1300 of FIG. 3 will be described in detail with reference to FIG. 5. Referring to FIGS. 1, 4 and 5, each of the first to nth memory modules 110 to 1n0 may store a corresponding embedding segment group, as described in FIG. 4. For example, the first memory module 110 may store the embedding segments SEG11 to SEGk1.

The memory modules 110 to 1n0 may gather at least one of the stored embedding segments. In an exemplary embodiment, the memory modules 110 to 1n0 may gather the embedding segments corresponding to the embeddings that are selected by the main processor 200. For example, the first memory module 110 may gather the embedding segments SEG11 to SEGk1 corresponding to the first embedding EBD1 to the k-th embedding EBDk.

The second memory module 120 may gather the embedding segments SEG12 to SEGk2 corresponding to the first embedding EBD1 to the k-th embedding EBDk.

The memory modules 110 to 1n0 may generate a reduced embedding REBD through the tensor operation with respect to the gathered embedding segments. In this case, each of the memory modules 110 to 1n0 may generate one of segments RES1 to RESn of the reduced embedding REBD. For example, the first memory module 110 may generate the reduced embedding segment RES1, based on the embedding segments SEG11 to SEGk1. The second memory module 120 may generate the reduced embedding segment RES2, based on the embedding segments SEG12 to SEGk2.

As described above, each of the memory modules 110 to 1n0 may gather the embedding segments and may generate the reduced embedding segment through the tensor operation with respect to the gathered embedding segments. In this case, the reduced embedding segments generated from the memory modules 110 to 1n0 may form the reduced embedding REBD. A size of the reduced embedding REBD may be less than the embeddings selected by the main processor 200 or the total embeddings stored in the memory modules 110 to 1n0. Accordingly, in the inference and training operation, when the reduced embedding REBD generated from the memory modules 110 to 1n0 is transferred to the main processor 200, the latency may be reduced under the limited bandwidth.

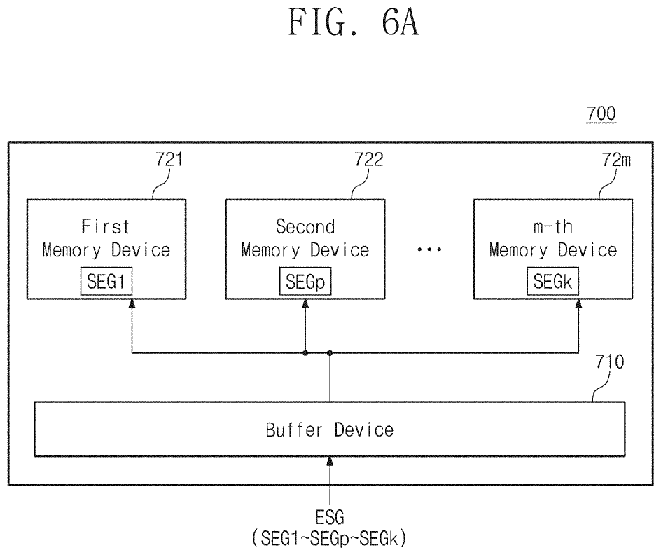

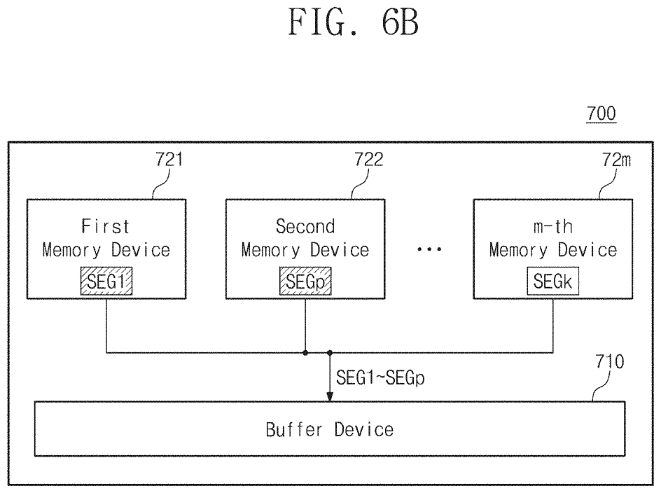

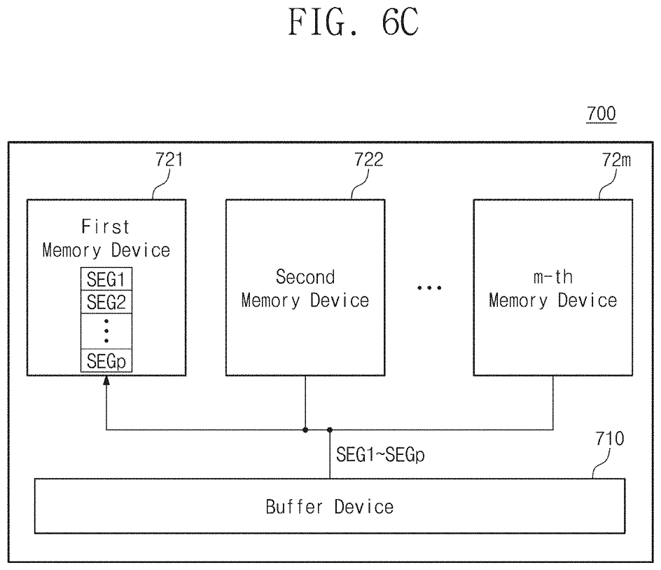

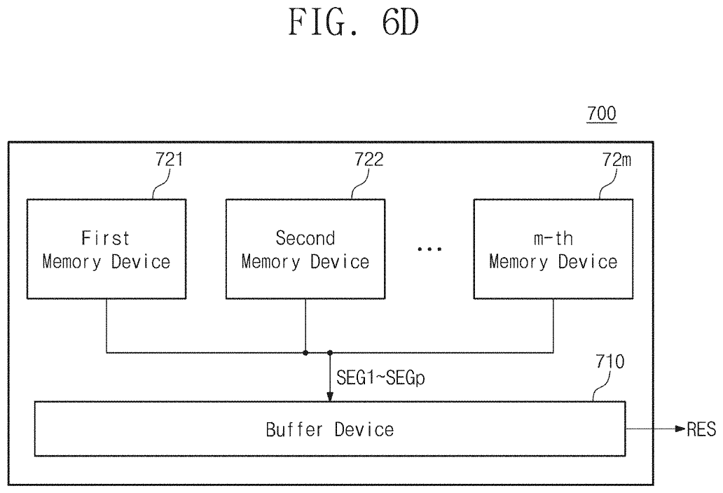

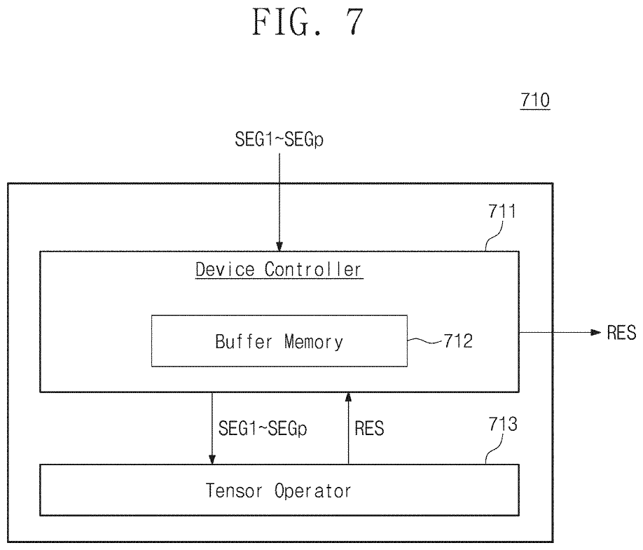

Hereinafter, a memory module according to embodiments of the inventive concept will be described in detail with reference to FIGS. 6A to 7.

FIGS. 6A to 6D are block diagrams illustrating a memory module according to an embodiment of the inventive concept. Specifically, an example in which a memory module 700 generates a reduced embedding segment RES will be described with reference to FIGS. 6A to 6D. The memory module 700 of FIGS. 6A to 6D may correspond to each of the memory modules 110 to 1n0 of FIG. 1. The memory module 700 may include a buffer device 710 and first to m-th memory devices 721 to 72m. The buffer device 710 and the memory devices 721 to 72m may be implemented with different semiconductor packages, and may be respectively disposed on one printed circuit board.

The buffer device 710 may control an operation of the memory devices 721 to 72m. The buffer device 710 may control the memory devices 721 to 72m in response to a command transmitted from an external host device (e.g., the main processor 200 of FIG. 1).

Each of the memory devices 721 to 72m may output data from internal memory cells or may store data in the internal memory cells, under the control of the buffer device 710. For example, each of the memory devices 721 to 72m may be implemented as a volatile memory device such as an SRAM and a DRAM or a nonvolatile memory device such as a flash memory, a PRAM, an MRAM, an RRAM, and an FRAM. For example, each of the memory devices 721 to 72m may be implemented as one chip or package.

In FIGS. 6A and 6D, the memory devices 721 to 72m are illustrated as “m” memory devices, but the memory module 700 may include at least one or more memory devices.

Referring to FIG. 6A, the buffer device 710 may receive an embedding segment group ESG. For example, the embedding segment group ESG may include first to k-th embedding segments SEG1 to SEGp to SEGk (where “p” is a natural number of “k” or less). For example, as described with reference to FIG. 4, the buffer device 710 may receive at least one of the embedding segment groups ESG1 to ESGn generated from the embeddings EBD1 to EBDk. The buffer device 710 may store the embedding segment group ESG in at least one of the memory devices 721 to 72m. For example, the buffer device 710 may store the first embedding segment SEG1 in the first memory device 721, may store the p-th embedding segment SEGp in the second memory device 722, and may store the k-th embedding segment SEGk in the m-th memory device 72m. The buffer device 710 may store the embedding segment group ESG such that the embedding segment group ESG is distributed in the memory devices 721 to 72m, but the inventive concept is not limited thereto. For example, the buffer device 710 may store the first to k-th embedding segments SEG1 to SEGk in the first memory device 721.

In another embodiment, the buffer device 710 may split each of the embedding segments SEG1 to SEGk into a plurality of slices and may store the slices in memory devices 721 to 72m. For example, the buffer device 710 may generate first to m-th slices by splitting the embedding segment SEG1 depending on the number (i.e., m) of the memory devices 721 to 72m. In this case, the buffer device 710 may store the first slice in the first memory device 721 and may store the second slice in the second memory device 722. Likewise, the buffer device 710 may store the remaining slices in corresponding memory devices. Accordingly, when the buffer device 710 reads each of the embedding segments SEG1 to SEGk from the memory devices 721 to 72m or writes each of the embedding segments SEG1 to SEGk in the memory devices 721 to 72m, the buffer device 710 may utilize a bus bandwidth between the buffer device 710 and the memory devices 721 to 72m to a maximum.

Referring to FIG. 6B, in the inference and training operation, the buffer device 710 may output the embedding segments SEG1 to SEGp stored in the memory devices 721 to 72m in response to an embedding lookup instruction from the external host device (e.g., the main processor 200 of FIG. 1). For example, the output embedding segments SEG1 to SEGp may correspond to the embeddings SEG1 to SEGp selected by the host device.

Referring to FIG. 6C, the buffer device 710 may store the output embedding segments SEG1 to SEGp in the consecutive address space among the memory spaces of the memory devices 721 to 72m. In an exemplary embodiment, the buffer device 710 may store the embedding segments SEG1 to SEGp in one of the memory devices 721 to 72m. For example, the buffer device 710 may store the embedding segments SEG1 to SEGp in the consecutive address space of the first memory device 721. Accordingly, the embedding segments SEG1 to SEGp may be gathered. That is, the embedding lookup operation may be performed.

Referring to FIG. 6D, the buffer device 710 may perform the tensor operation, based on the gathered embedding segments SEG1 to SEGp. The buffer device 710 may process the embedding segments SEG1 to SEGp through the tensor operation. For example, the buffer device 710 may perform the tensor operation such as the addition operation, the subtraction operation, the multiplication operation, the concatenation operation, and the average operation with respect to the embedding segments SEG1 to SEGp. Accordingly, the buffer device 710 may generate the reduced embedding segment RES. The buffer device 710 may output the generated reduced embedding segment RES. For example, the buffer device 710 may transmit the reduced embedding segment RES to the main processor 200 of FIG. 1.

For example, unlike described in FIGS. 6A to 6D, the embedding segments SEG1 to SEGp are transmitted to the main processor 200 of FIG. 1, for the embedding lookup, and the embedding segments SEG1 to SEGp transmitted to the main processor 200 are transmitted back to the memory module 700 and then may be stored in the consecutive address space of the memory module 700. In this way, when the embedding segments are transferred between each of the plurality of memory modules and the main processor 200, the latency of the embedding lookup may be increased due to the limited bandwidth.

In contrast, as described above, the memory module 700 may gather the embedding segments SEG1 to SEGp without transmitting the embedding segments SEG1 to SEGp to an outside. Accordingly, the memory module 700 may gather the embedding segments SEG1 to SEGp regardless of the limited bandwidth. That is, even though the number of memory modules is increased, each of the memory modules may perform the embedding lookup without a limitation of the bandwidth. Accordingly, an available memory bandwidth of the neural network acceleration system according to embodiments of the inventive concept may increase in proportion to the number of memory modules, as the number of memory modules increases.

Although it is described that the reduced embedding segment RES is generated through the tensor operation in FIG. 6A to 6D, based on the embedding segments SEG1 to SEGp gathered by the memory module 700, the inventive concept is not limited thereto. For example, the memory module 700 may transmit the gathered embedding segments SEG1 to SEGp to the main processor 200 without performing the tensor operation separately.

FIG. 7 is a block diagram illustrating an example of a buffer device of FIGS. 6A to 6D. Referring to FIGS. 6A to 7, the buffer device 710 may include a device controller 711 and a tensor operator 713. The device controller 711 may control operations of the buffer device 710 and the memory devices 721 to 72m. For example, the device controller 711 may control an operation of the tensor operator 713.

The tensor operator 713 may perform the tensor operation under a control of the device controller 711. For example, the tensor operator 713 may be implemented as an arithmetic logic unit that performs the addition operation, the subtraction operation, the multiplication operation, the concatenation operation, and the average operation. The tensor operator 713 may provide result data calculated through the tensor operation to the device controller 711.

The device controller 711 may include a buffer memory 712. The device controller 711 may store data provided from the outside or data generated therein in the buffer memory 712. The device controller 711 may output data stored in the buffer memory 712 to the outside of the buffer device 710. The buffer memory 712 in FIG. 7 is illustrated as being located inside the device controller 711, but the inventive concept is not limited thereto. For example, the buffer memory 712 may be located outside the device controller 711.

The device controller 711 may output the embedding segments SEG1 to SEGp from the memory devices 721 to 72m. For example, the device controller 711 may output the embedding segments SEG1 to SEGp gathered in one of the memory devices 721 to 72m. The device controller 711 may store the output embedding segments SEG1 to SEGp in the buffer memory 712. The device controller 711 may provide the embedding segments SEG1 to SEGp stored in the buffer memory 712 to the tensor operator 713.

The tensor operator 713 may perform the tensor operation, based on the embedding segments SEG1 to SEGp, and may generate the reduced embedding segment RES. The tensor operator 713 may transmit the generated reduced embedding segment RES to the device controller 711. The device controller 711 may store the reduced embedding segment RES in the buffer memory 712. The device controller 711 may output the reduced embedding segment RES stored in the buffer memory 712. For example, the device controller 711 may transmit the reduced embedding segment RES to the main processor 200 of FIG. 1.

As described above, the memory module 700 according to an embodiment of the inventive concept may generate the reduced embedding segment RES by performing the tensor operation with respect to the embedding segments SEG1 to SEGp. In this case, the data size of the reduced embedding segment RES may be less than the data size of the entire embedding segments SEG1 to SEGp. Accordingly, when the reduced embedding segment RES is transmitted to the main processor 200 through the first bus 1001 or is transmitted to the dedicated processor 300 through the first bus 1001 and the second bus 1002, the latency may be reduced under the limited bandwidth. Accordingly, the main processor 200 or the dedicated processor 300 may quickly perform the inference and training operation, based on the reduced embedding segments RES (i.e., reduced embedding REBD).

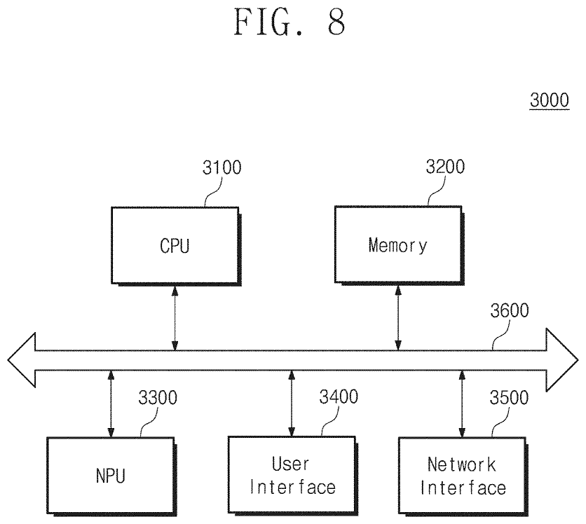

FIG. 8 is a block diagram illustrating an expanded example of a neural network acceleration system according to embodiments of the inventive concept. Referring to FIG. 8, a neural network acceleration system 3000 may include a central processing unit 3100, a memory 3200, a neural processing unit 3300, a user interface 3400, a network interface 3500, and a bus 3600. For example, the neural network acceleration system 3000 may be implemented as one of a desktop, a laptop, an embedded system, a server, an automobile, a mobile device, and an artificial intelligence system.

The central processing unit 3100 may control the neural network acceleration system 3000. For example, the central processing unit 3100 may control operations of the memory 3200, the neural processing unit 3300, the user interface 3400, and the network interface 3500. The central processing unit 3100 may transmit data and commands to components of the neural network acceleration system 3000 through the bus 3600 and may receive data from the components. For example, the central processing unit 3100 may be implemented with one of the main processors 200 and 500 described with reference to FIGS. 1 to 7.

The memory 3200 may store data or may output stored data. The memory 3200 may store data to be processed or data processed by the central processing unit 3100 and the neural processing unit 3300. For example, the memory 3200 may include a plurality of memory modules 700 described with reference to FIGS. 1 to 7. Accordingly, the memory 3200 may store the embedding segments and may generate the reduced embedding through the tensor operation on the embedding segments. In the inference and training operation, the memory 3200 may transfer the reduced embedding to the central processing unit 3100 or the neural processing unit 3300.

The neural processing unit 3300 may perform the inference and training operation, based on various neural network algorithms under the control of the central processing unit 3100. For example, the neural processing unit 3300 may be implemented with one of the dedicated processors 300 and 600 described with reference to FIGS. 1 to 7. The neural processing unit 3300 may perform the inference and training operation, based on the reduced embedding transferred from the memory 3200. The neural processing unit 3300 may transfer a result of the inference and training to the central processing unit 3100. Accordingly, the central processing unit 3100 may output the result of the inference and training through the user interface 3400 or may control the neural network acceleration system 3000 depending on the result of the inference and training.

It is described that the neural processing unit 3300 in FIG. 8 performs the inference and training operation, but the inventive concept is not limited thereto. For example, the neural network acceleration system 3000 may include a graphics processing device instead of the neural processing unit 3300. In this case, the graphics processing device may perform the inference and training operation, based on the neural network.

The user interface 3400 may be configured to exchange information with a user. The user interface 3400 may include a user input device that receives information from the user, such as a keyboard, a mouse, a touch panel, a motion sensor, a microphone, etc. The user interface 3400 may include a user output device that provides information to the user, such as a display device, a speaker, a beam projector, a printer, etc. For example, the neural network acceleration system 3000 may start the inference and training operation through the user interface 3400 and may output the result of the inference and training.

The network interface 3500 may be configured to exchange data wirelessly or wiredly with an external device. For example, the neural network acceleration system 3000 may receive the embeddings learned from the external device through the network interface 3500. The neural network acceleration system 3000 may transmit inference and training results to the external device through the network interface 3500.

The bus 3600 may transfer commands and data between components of the neural network acceleration system 3000. For example, the bus 3600 may include the buses 1001, 1002, 2001, and 2002 described with reference to FIGS. 1 to 7.

According to an embodiment of the inventive concept, the neural network acceleration system may include a memory module capable of preprocessing stored embeddings. The memory module may reduce a data size of embeddings to be transmitted to a processor through the preprocessing. The memory module may transmit the embedding generated by the preprocessing to the processor, and the processor may perform an inference and a training operation, based on the embedding. As such, as the embeddings are preprocessed by the memory module, the size of data transmitted from the memory module to the processor may be reduced. Accordingly, latency depending on embedding transmission between the memory module and the processor may be reduced, and the neural network acceleration system may quickly perform an inference and a training operation.

The contents described above are specific embodiments for implementing the inventive concept. The inventive concept may include not only the embodiments described above but also embodiments in which a design is simply or easily capable of being changed. In addition, the inventive concept may also include technologies easily changed to be implemented using embodiments. Therefore, the scope of the inventive concept is not limited to the described embodiments but should be defined by the claims and their equivalents.

What is claimed is:

1. A neural network acceleration system comprising:
a first memory module configured to generate a first reduced embedding segment through a tensor operation, based on a first segment of a first embedding and a second segment of a second embedding;
a second memory module configured to generate a second reduced embedding segment through the tensor operation, based on a third segment of the first embedding and a fourth segment of the second embedding; and
a processor configured to process a reduced embedding including the first reduced embedding segment and the second reduced embedding segment, based on a neural network algorithm.

2. The neural network acceleration system of claim 1, wherein the first embedding corresponds to a first object of a specific category, and wherein the second embedding corresponds to a second object of the specific category.

3. The neural network acceleration system of claim 1, wherein the first memory module includes:
at least one memory device configured to store the first segment and the second segment; and
a tensor operator configured to perform the tensor operation, based on the first segment and the second segment.

4. The neural network acceleration system of claim 3, wherein the at least one memory device is implemented as a dynamic random access memory.

5. The neural network acceleration system of claim 1, wherein a size of the first segment is the same as a size of the third segment.

6. The neural network acceleration system of claim 1, wherein a data size of the reduced embedding is less than a total data size of the first embedding and the second embedding.

7. The neural network acceleration system of claim 1, wherein the tensor operation includes at least one of an addition operation, a subtraction operation, a multiplication operation, a concatenation operation, and an average operation.

8. The neural network acceleration system of claim 1, further comprising:
a bus configured to transfer the first reduced embedding segment from the first memory module and the second reduced embedding segment from the second memory module to the processor, based on a preset bandwidth.

9. The neural network acceleration system of claim 1, wherein the first memory module is further configured to gather the first segment and the second segment in a memory space corresponding to consecutive addresses, and
wherein the first reduced embedding segment is generated based on the gathered first and second segments.

10. A neural network acceleration system comprising:
a first memory module configured to generate a first reduced embedding segment through a tensor operation, based on a first segment of a first embedding and a second segment of a second embedding;
a second memory module configured to generate a second reduced embedding segment through the tensor operation, based on a third segment of the first embedding and a fourth segment of the second embedding;
a main processor configured to receive the first reduced embedding segment and the second reduced embedding segment through a first bus; and
a dedicated processor configured to process a reduced embedding including the first reduced embedding segment and the second reduced embedding segment, which are transferred through a second bus, based on a neural network algorithm.

11. The neural network acceleration system of claim 10, wherein the first embedding corresponds to a first object of a specific category, and wherein the second embedding corresponds to a second object of the specific category.

12. The neural network acceleration system of claim 10, wherein the first memory module includes:
at least one memory device configured to store the first segment and the second segment; and
a tensor operator configured to perform the tensor operation, based on the first segment and the second segment.

13. The neural network acceleration system of claim 10, wherein the first bus is configured to transfer the first reduced embedding segment and the second reduced embedding segment from the first memory module and the second memory module, respectively, to the main processor, based on a first bandwidth, and
wherein the second bus is configured to transfer the first reduced embedding segment and the second reduced embedding segment from the main processor to the dedicated processor, based on a second bandwidth.

14. The neural network acceleration system of claim 10, wherein the main processor is further configured to store the first segment generated by splitting the first embedding and the second segment generated by splitting the second embedding in the first memory module, and further configured to store the third segment generated by splitting the first embedding and the fourth segment generated by splitting the second embedding in the second memory module.

15. The neural network acceleration system of claim 14, wherein the main processor is further configured to split the first embedding such that a data size of the first segment is the same as a data size of the third segment, and further configured to split the second embedding such that a data size of the second segment is the same as a data size of the fourth segment.

16. The neural network acceleration system of claim 10, wherein the dedicated processor includes at least one of a graphic processing device and a neural network processing device.

17. The neural network acceleration system of claim 10, wherein the first memory module is further configured to gather the first segment and the second segment in a memory space corresponding to consecutive addresses, and
wherein the first reduced embedding segment is generated based on the gathered first and second segments.

18. A method of operating a neural network acceleration system including a first memory module, a second memory module, and a processor, the method comprising:
storing, by the processor, a first segment generated by splitting a first embedding and a second segment generated by splitting a second embedding in the first memory module, and storing, by the processor, a third segment generated by splitting the first embedding and a fourth segment generated by splitting the second embedding in the second memory module;
generating, by the first memory module, a first reduced embedding segment through a tensor operation, based on the first segment and the second segment, and generating, by the second memory module, a second reduced embedding segment through the tensor operation, based on the third segment and the fourth segment; and
processing, by the processor, a reduced embedding including the first reduced embedding segment and the second reduced embedding segment, based on a neural network algorithm.

19. The method of claim 18, wherein the first embedding corresponds to a first object of a specific category, and wherein the second embedding corresponds to a second object of the specific category.

20. The method of claim 18, wherein the generating of the first reduced embedding segment, by the first memory module includes:
gathering, by the first memory module, the first segment and the second segment in a memory space corresponding to consecutive addresses; and
generating the first reduced embedding segment, based on the gathered first and second segments.
